(19) United States
(12) Patent Application Publication
(10) Pub. No.: US 2013/0015057 A1
(43) Pub. Date: Jan. 17, 2013

(54) CATHODE SPUTTER DEPOSITION OF A Cu(In,Ga)X2 THIN FILM

(71) Applicants: Simon Perraud, Bandol (FR); Joel Dufourco, Puyoo (FR); Frederic Gaillard, Voiron (FR); Sebastien Noel, Rives (FR); Emmanuelle Rouviere, Saint-Egreve (FR)

(72) Inventors: Simon Perraud, Bandol (FR); Joel Dufourco, Puyoo (FR); Frederic Gaillard, Voiron (FR); Sebastien Noel, Rives (FR); Emmanuelle Rouviere, Saint-Egreve (FR)

(73) Assignee: COMMISSARIAT A L'ENERGIE ATOMIQUE ET AUX ENERGIES ALTERNATIVES, Paris (FR)

(21) Appl. No.: 13/513,328

(22) PCT Filed: Nov. 29, 2010
(86) PCT No.: PCT/FR2010/000792

§ 371 Date: Sep. 18, 2012

(30) Foreign Application Priority Data
Dec. 2, 2009 (FR) 09 05811

(51) Int. Cl. C23C 14/34; C23C 14/14

(52) U.S. Cl. 204/192.15; 204/298.07

(57) ABSTRACT

A method and device for the deposition of a film made of a semiconductive material having the formula Cu(In, Ga)X₂, where X is S or Se, involves cathode sputter deposition of Cu, In, and Ga onto at least one surface of a substrate and simultaneous deposition of X in vapor phase onto the surface in a cathode chamber. A vapor form of X or its precursor is moved in a first laminar gas flow parallel to and in contact with the surface, and is simultaneously moved in a second laminar gas flow for inert gas parallel to the first laminar gas flow and located between the first laminar gas flow and a sputtering target(s), to confine the first laminar gas flow to the area around the substrate.

### RELATED APPLICATIONS

The present application is a National Phase of International Application Number PCT/FR2010/000792, filed Nov. 29, 2010, and claims priority from French Application Number 09 05811, filed Dec. 2, 2009.

### BACKGROUND

The invention relates to a method and a device for depositing a film of semiconductive material having the formula Cu(In,Ga)X₂ where X is S or Se.

Films, in particular thin films, of semiconductive material Cu(In,Ga)Se₂ or Cu(In,Ga)S₂ hereinafter called (CIGX), are used for the production of low-cost high-efficiency photovoltaic cells, because the method involved is easily applicable to the case of deposition on substrates having large surface areas, in the range of 1 m² or more.

Various methods are known for forming a thin film of CIGX, in particular of CIGSe.

One of these methods is a cathode sputtering method comprising two steps carried out in two distinct units: the first step consists in the cathode sputtering deposition of a thin film containing the metal precursors (Cu, In and Ga) and the second step consists of the selenization or sulfurization of said metal film by annealing in an atmosphere containing Se or S (in the form of Se or S vapor, H₂Se or H₂S gas, etc.), in order to form the desired compound.

Such a method is described by Ermer et al. in U.S. Pat. No. 4,798,660 (1989).

In order to reduce the duration of the method and the investment cost, Thornton et al. in U.S. Pat. No. 5,439,575 (1995) have proposed the formation of a thin film of CIGSe, by a single-step cathode sputtering technique.

In this method, the metal elements (Cu, In and Ga) are provided on the substrate by cathode sputtering, whereas the Se reaches the substrate in the form of Se vapor evaporated from a crucible itself located in the same cathode sputtering chamber.

The substrate must be heated during the deposition.

Thin films of CIGSe prepared by this method are used to produce photovoltaic cells with an energy efficiency higher than 10% (Nakada et al., Jpn. J. Appl. Phys. 34, 4715 (1995)).

In the hybrid method combining cathode sputtering and evaporation, the selenium is provided in the form of selenium vapor evaporated from a crucible.

However, evaporation from a crucible gives rise to a vapor flow directed in a relatively wide angular distribution, and it is also known that the excess selenium reaching the heated substrate is reevaporated.

In consequence, the chamber is completely saturated with selenium vapor, which condenses very easily on any unheated surface. The same problem arises with sulfur.

In other words, undesirable deposits of selenium or sulfur appear both on the sputtering targets, making it difficult to control the sputtering rates and hence the speed of deposition, and also on all the cold walls of the chamber, entailing frequent maintenance of the equipment.

### SUMMARY

It is an object of the invention to overcome the drawbacks of the prior art methods by proposing a method and a device for forming a film, in particular a thin film, of CIGX, where X is Se or S, by a single-step cathode sputtering technique, but one in which the selenium or sulfur is not, or is less, deposited on the cold walls of the cathode sputtering chamber.

For this purpose, the invention proposes a device for depositing a film of Cu(In,Ga)X₂, where X is Se or S or a mixture thereof, onto at least one surface of a substrate, comprising a cathode sputtering chamber, comprising:
a substrate holder,
means for heating the substrate holder,
at least one sputtering target holder, the substrate holder being positioned opposite at least one sputtering target holder and separated therefrom,
a first injection tube 3 for injecting a first laminar flow of inert gas containing X or a precursor of X, in vapor form,
   characterized in that it further comprises a second injection tube for injecting a second laminar flow of inert gas, the inlet orifice in the cathode sputtering chamber of which is located between the inlet orifice in the cathode sputtering chamber of the first injection tube and the at least one target holder, so that the second laminar flow of inert gas entering via the inlet orifice of the second injection tube is parallel to the first laminar flow of inert gas containing X, or a precursor thereof, in vapor form, and confines the first laminar flow of inert gas containing X, or a precursor of X, in vapor form, to the area around the substrate holder.

In a first preferred embodiment, the device of the invention further comprises an enclosure comprising means for vaporizing X, this enclosure being in fluidic connection with the first injection tube and the cathode sputtering chamber.

In a second preferred embodiment, the device of the invention comprises an enclosure comprising means for creating a plasma for decomposing and vaporizing a precursor of X, this enclosure being in fluidic connection with the first injection tube and the cathode sputtering chamber.

In all the embodiments, the cathode sputtering chamber further, and preferably, comprises a grid optionally provided with cooling means, the grid extending along the whole length of the cathode sputtering chamber parallel to the substrate holder and between the inlet orifice of the first injection tube and the orifice of the second injection tube.

In a particular embodiment, the inventive device comprises two sputtering targets located next to one another.

However, the inventive device may also comprise three sputtering targets located next to one another.

The invention also proposes a method for depositing a film of Cu(In,Ga)X₂ where X is Se or S or a mixture thereof, which comprises a step of depositing Cu, In and Ga by cathode sputtering from at least one sputtering target, on at least one surface of a substrate, simultaneously with a step of X vapor deposition on said at least one surface in a cathode sputtering chamber,

characterized in that X, or a precursor thereof, in vapor form, is moved in the form of a first laminar gas flow, the traveling path of which is parallel to the at least one surface of the substrate and in contact therewith, simultaneously with a second laminar gas flow of inert gas, the traveling path of which is:
parallel to the traveling path of the first laminar gas flow, and
between the traveling path of the first laminar gas flow and the surface of the sputtering target(s), thereby confining the first laminar gas flow to the area around the substrate.

According to an advantageous feature, the speed of the second laminar gas flow is higher than the speed of the first laminar gas flow.

Advantageously, the first and second laminar gas flows, each independently of one another, have a Knudsen number K=L/a where L is the mean distance traveled by an atom or a molecule between two collisions and a is a characteristic length, approximately the same as, or equal to, the distance between the sputtering target(s) and the substrate, such that ≦K=10⁻² and/or a Reynolds number R≦=1000.

In a first preferred embodiment, X is deposited from a precursor of X, having the formula R₂X where R is H, Me, Et, iPr or tBu.

However, X as such may also be vaporized and entrained in said first laminar gas flow containing an inert gas such as argon in the cathode sputtering chamber.

Preferably, said second laminar gas flow is a laminar flow of argon.

In a particular embodiment, the precursor of X is decomposed by plasma before injection into the cathode sputtering chamber.

Preferably, said first laminar gas flow and said second laminar gas flow are separated from one another by a grid, which is preferably cooled.

### BRIEF DESCRIPTION OF THE DRAWING

The invention will be better understood and other features and advantages thereof will appear more clearly by reading the following detailed description which is made with reference to the single appended FIGURE which schematically shows a device according to the invention for implementing the method of the invention.

### DETAILED DESCRIPTION

The device of the invention will be described with reference to the single appended FIGURE which schematically represents such a device.

As shown in the FIGURE, the device of the invention, for the deposition of a film, in particular a thin film, generally having a thickness of between 100 nm and 5 μm inclusive, preferably between 1 and 2 inclusive, of a compound of Cu(In,Ga)X₂ where X is either selenium (Se), or sulfur (S), comprises a conventional cathode sputtering chamber, denoted 1 in the FIGURE: said chamber 1 comprises in particular at least one cathode sputtering target holder, denoted 7 in the FIGURE, intended to receive a sputtering target.

The sputtering target holder 7 may receive a single sputtering target. In this case, said target is a Cu—In—Ga alloy.

However, it may also accommodate either two target holders each receiving a sputtering target, or two cathode sputtering targets supported on the same target holder, for example in which one of the targets is made from a Cu—Ga alloy, and the other target is made from In.

However, it may even accommodate three cathode sputtering targets placed on the same cathode sputtering target holder shown in the FIGURE, or even three targets placed on three target holders. For example, one of the targets is made from Cu, the other from Ga and the third from In.

Said at least one cathode sputtering target holder 7 is positioned opposite a substrate holder, denoted 6 in the FIGURE, which is intended to receive a substrate on at least one surface of which the thin film is to be deposited.

If the device of the invention only comprises one target, the target holder will advantageously be parallel to the substrate.

If the device of the invention comprises two or more targets, it will be advantageous to position the targets symmetrically and slightly converging toward a zone of the substrate holder.

The substrate holder 6 is provided with heating means, not shown, for heating the substrate.

If necessary, the chamber 1 may also be provided with a vacuum inlet and a vacuum creating device.

The device of the invention also comprises an enclosure, denoted 2 in the FIGURE, intended to vaporize the element X or to decompose and vaporize the precursor thereof, as shown below.

Said enclosure 2 is separated from the chamber 1 but connected thereto via an injection tube, denoted 3 in the FIGURE, provided with heating means, not shown.

The inlet of the injection tube 3 is located on the walls of the chamber 1, but under the substrate holder 6 to allow contact between the vaporized element X and the substrate.

Thus, the vapors of the element X enter the chamber 1 in the form of a first laminar flow of which the traveling path is shown by the arrows denoted 9 in the FIGURE. When the vapors of the element X make contact with the substrate, the element X present in excess on the heated substrate is reevaporated and then entrained by the first laminar flow containing the element X as shown by the arrows denoted 5 in the FIGURE.

For being able of depositing the desired thin film in a single step while avoiding the deposition of X on the cold walls of the device, the device of the invention further comprises an injection tube denoted 4 in the FIGURE for injecting an inert gas, such as argon, helium or nitrogen into the chamber 1.

Preferably, the gas is argon.

The injection tube 4 has its inlet located under the inlet of the injection tube 3 and injects a second laminar flow, preferably of argon, under the first laminar flow transporting the element X in vapor form. Said second laminar flow follows the path as shown by the arrows denoted 12 in the FIGURE.

The simultaneous injection of these two laminar flows enables to confine the vapors of the element X to the area around the surface of the substrate and thereby to avoid undesirable deposits of X on the sputtering target and on the cold walls of the chamber 1.

The chamber 1 also comprises means for removing the laminar gas flows and, obviously, means for sputtering the sputtering target(s).

Thus, the method of the invention consists in depositing, by cathode sputtering of at least one cathode sputtering target, the metallic elements Cu, In and Ga on at least one surface of a substrate heated by means of the heating means of the substrate holder 6.

In general, the element X is conveyed in vapor form:
either the element X is vaporized in the enclosure 2 and introduced in vapor form via the heated injection tube 3. The injection tube 3 is heated to a sufficient temperature to maintain the element X in vapor form. The element X is entrained into the chamber 1 by an inert gas such as argon, nitrogen or helium, in the form of a first laminar flow. Argon is preferably used. For this purpose, the enclosure 2 is provided with means for vaporizing the element X and with an inert gas inlet denoted 10 in the FIGURE,
or a gas of a precursor of X having or not having undergone a plasma is conveyed into the chamber 1, in which case the enclosure is provided with means for decomposing the precursor and vaporizing it. In this case, when the precursor of X decomposed in gas form makes contact with the surface on which the film is to be deposited, it reacts chemically with said surface.

In all cases, at the same time as the element X in vapor form is introduced into the chamber 1, a second laminar flow of inert gas is introduced under the first flow containing the element X or its precursor. Along a traveling path parallel to that of the first laminar flow, which passes under the first laminar flow, that is to say, between the first laminar flow and the cathode sputtering target(s).

Thus, the chamber 1 also comprises an injection tube denoted 4 in the FIGURE, for injecting an inert gas, such as argon, helium or nitrogen.

The preferred gas is argon.

The chamber 1 also comprises a tube for removing said inert gas and, obviously, means for sputtering the target(s).

If necessary, the chamber 1 may also be provided with a vacuum inlet and a device for placing the enclosure under vacuum.

The device of the invention also comprises an enclosure, denoted (2) in the FIGURE, for vaporizing the element X or for decomposing-vaporizing a precursor thereof.

Said enclosure 2 is separated from the chamber 1 but connected thereto via an injection tube, denoted 3 in the FIGURE, provided with heating means.

The inlet of the injection tube 3 is located under the substrate holder 10 to allow contact between the vaporized element X and the substrate.

Thus, the vapors of the element X enter the chamber 1 in the form of a first laminar gas flow of which the traveling path is shown by the arrows denoted 9 in the FIGURE. When the vapors of the element X make contact with the substrate, the element X present in excess on the heated substrate is reevaporated and then entrained by the laminar flow of the element X as shown by the arrows denoted 5 in the FIGURE. This enables to deposit the desired thin film in a single step and avoid the deposition of X on the cold walls of the device.

The injection tube 4 has its inlet located under the inlet of the injection tube 3 and injects a second laminar flow of inert gas, preferably of argon, under the first laminar flow transporting the element X in vapor form. Said second laminar flow follows the path shown by the arrows denoted 12 in the FIGURE.

The second laminar flow of inert gas enables to confine the vapors of the element X to the area around the surface of the substrate and thereby to avoid undesirable deposits of X on the sputtering target and on the cold walls of the chamber 1.

Thus, the method of the invention consists in depositing, by cathode sputtering of at least one cathode sputtering target, the metallic elements Cu, In and Ga onto the heated substrate on at least one surface of a heated substrate thanks to the heating means of the substrate holder 10.

The element X is vaporized in the enclosure 2 and is introduced in vapor form via the heated injection tube 3.

The injection tube 3 is heated to a sufficient temperature to maintain the element X in vapor form.

The element X is entrained into the chamber 1 by an inert gas such as argon, nitrogen or helium.

Argon is preferably used. For this purpose, the enclosure 2 for vaporizing the element X is provided with an inert gas inlet, denoted 10 in the FIGURE.

At the same time as the element X in vapor form is introduced into the chamber 1, a second laminar flow, of inert gas, is introduced under the first flow of the element X and between said flow and the cathode sputtering target(s).

The first laminar flow of the element X is removed from the chamber 1 via the discharge tube denoted 13 in the FIGURE and the inert gas flow is removed from the chamber 1 via the discharge tube denoted 14 in the FIGURE.

The first laminar flow of the element X is therefore formed by the passage of inert gas through the enclosure 2 for vaporizing the element X, and the gas mixture is then conveyed into the injection tube 3.

Said injection tube 3 must be heated, in the case of selenium, to a temperature above 200° C., to prevent the selenium from condensing before injection.

The element X present in excess on the heated substrate is reevaporated and entrained in the laminar flow of the X vapors as shown in the FIGURE by the arrows denoted 5.

The second laminar flow of inert gas plays a crucial role for protecting the sputtering target and also the cold walls of the enclosure 1, because the vapors of the element X diffusing from the first flow containing it in vapor form toward the second inert gas flow are rapidly entrained by the second inert gas flow before reaching the sputtering target or the cold walls.

The two flows are laminar flows.

In order to be in laminar flow conditions, the Knudsen number K must be lower than 0.01 to avoid molecular flow conditions and the Reynolds number R must be lower than 1000 to avoid turbulent flow conditions.

The Knudsen number is given by the formula:

K=L/a,

where L is the mean free path in the gas, that is to say, the mean distance traveled by an atom or a molecule between two collisions, said distance being inversely proportional to the gas pressure, and a is a length characteristic of the approximate distance between the sputtering target and the substrate.

The Reynolds number is given by the formula:

R=νρa/η.

where ν is the flow speed of the gas flow, ρ the gas density, and η the gas viscosity.

Thus, for a given geometry, and for a given gas mixture, obtaining laminar flow conditions requires having a sufficiently high pressure (that is to say a sufficiently short mean free path) and a sufficiently low flow speed.

A first compromise is related to the gas pressure: a high pressure is necessary to avoid molecular flow conditions, whereas a low pressure favors a high deposition rate of the sputtered elements.

The pressure must therefore be decreased while remaining in the case K<0.01.

For a typical distance of about 10 cm between the sputtering target and the substrate, the mean free path L must be about 1 mm to have K≈0.01, or a pressure of a few tens of mTorr at the temperatures considered.

Such a pressure remains compatible with high deposition rates in magnetron mode.

A second compromise relates to the flow speed of the gas flow: a low flow speed is necessary to avoid turbulent flow conditions, whereas high flow speed favors the effective protection of the sputtering target and the cold walls against the vapors of the element X: the higher the flow speed, the faster the vapors of element X having diffused from the flow containing it in vapor form toward the inert gas flow are entrained by the inert gas flow, which means that their residence time near the target or the cold walls is shorter.

In other words, both of the gas flows must be laminar but at the turbulence limit, that is to say they must, each independently of the other, have a Reynolds number ≦1000 and, preferably, the speed of the second laminar gas flow must be higher than the speed of the first laminar gas flow.

To further improve the inventive device and method, a grid denoted 8 in the FIGURE, optionally cooled, can be placed at the interface between the two laminar flows, in the inventive device, in order to act as a cold trap for the Se or S vapors.

Thus, in the method of the invention, the first flow containing the element X in vapor form is introduced between the substrate and the cooled grid 8 and the second inert gas flow is introduced between the grid 8 and the cathode sputtering target.

The element X may be obtained either by vaporizing the element X itself, or by chemical reaction on the substrate of one of its precursors, such as molecules having the formula R₂X where R=H, Me (methyl), Et (ethyl), iPr (isopropyl) or tBu (tertbutyl).

These precursor molecules may be decomposed by plasma in the enclosure 2, before injecting the gas.

Thus, the enclosure 2 may also comprise a device for decomposition of the molecules by plasma.

As to the cathode sputtering target(s), they may be rotating cylindrical targets.

In order to understand the invention better, an embodiment is now described, as a purely illustrative and nonlimiting example.

### Example

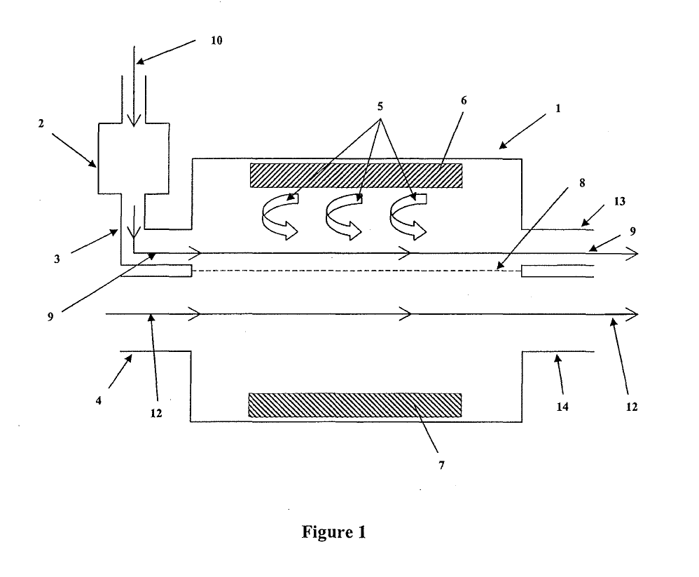

A device such as shown in FIG. 1 is used.

The substrate is heated to 820 K.

The distance a between the sputtering target and the substrate is 10 cm.

The pressure is 50 mTorr.

The first gas flow containing Se and argon is heated to 600 K and is injected via the orifice 3, at the same time as a second gas flow of inert gas, argon in this case, which is also heated to 600 K. The speeds of the first and second gas flows are both 10 m/s.

Thus, these gas flows have a Knudsen number K of about 10⁻².

The Reynolds coefficient of these two gas flows is 2.

The substrate is coated with a Cu(In,Ga)Se₂ film by cathode sputtering from a target consisting of Cu(In,Ga) and the simultaneous injection of the two abovementioned gas flows.

1. A device for depositing a film of Cu(In,Ga)X₂, where X is Se or S or a mixture thereof, onto at least one surface of a substrate, comprising a cathode sputtering chamber, comprising:
a substrate holder,
means for heating the substrate holder,
at least one sputtering target holder,
the substrate holder being positioned opposite at least one sputtering target holder and separated therefrom,
a first injection tube for injecting a first laminar flow of inert gas containing X or a precursor of X, in vapor form,
wherein it further comprises a second injection tube for injecting a second laminar flow of inert gas, the inlet orifice in the chamber of which is located between the inlet orifice in the chamber of the first injection tube and the at least one target holder,
so that the second laminar flow of inert gas entering via the inlet orifice of the second injection tube is parallel to the first laminar flow of inert gas containing X, or a precursor thereof, in vapor form, and confines the first laminar flow of inert gas containing X, or a precursor of X, in vapor form, to the area around the substrate holder.

2. The device as claimed in claim 1, wherein it further comprises an enclosure comprising means for vaporizing X, the enclosure being in fluidic connection with the first injection tube and the chamber.

3. The device as claimed in claim 1, wherein it further comprises an enclosure comprising means for creating a plasma for decomposing and vaporizing the precursor of X, the enclosure being in fluidic connection with the first injection tube and the chamber.

4. The device as claimed in claim 1, wherein the chamber further comprises a grid, optionally provided with cooling means, extending along the whole length of the chamber parallel to the substrate holder and between the inlet orifice of the first injection tube and the orifice of the second injection tube.

5. The device as claimed in claim 1, wherein it comprises two sputtering targets located next to one another.

6. The device as claimed in claim 1, wherein it comprises three sputtering targets located next to one another.

7. A method for depositing a film of Cu(In,Ga)X₂ where X is Se or S, or a mixture thereof comprising:
a step of depositing Cu, In and Ga by cathode sputtering from at least one sputtering target, on at least one surface of a substrate, simultaneously with a step of X vapor deposition on said at least one surface in a cathode chamber, wherein X, or a precursor thereof, in vapor form, is moved in the form of a first laminar gas flow, the traveling path of which is parallel to the at least one surface of the substrate and in contact therewith, simultaneously with a second laminar gas flow of inert gas, the traveling path of which is:
parallel to the traveling path of the first laminar gas flow, and
between the traveling path of the first laminar gas flow and the surface of the sputtering target(s),
thereby confining the first laminar gas flow to the area around the substrate.

8. The method as claimed in claim 7, wherein the speed of the second laminar gas flow is higher than the speed of the first laminar gas flow.

9. The method as claimed in claim 7, wherein the first and second laminar gas flows, each independently of one another, have a Knudsen number K=L/a where L is the mean distance traveled by an atom or a molecule between two collisions and a is the distance between the sputtering target(s) and the substrate, such that K≦10⁻².

10. The method as claimed in claim 7, wherein the first and second laminar gas flows, each independently of one another, have a Reynolds number R≦1000.

11. The method as claimed in claim 7, wherein X is deposited from a precursor of X, having the formula R₂X where R is H, Me, Et, iPr or tBu.

12. The method as claimed in claim 7, wherein X is vaporized and entrained in said first laminar gas flow containing an inert gas such as argon in the chamber.

13. The method as claimed in claim 7, wherein said second laminar gas flow is a laminar flow of argon.

14. The method as claimed in claim 11, wherein the precursor of X is decomposed by plasma before injection into the chamber.

15. The method as claimed in claim 7, wherein that said first laminar flow and said second laminar flow are separated from one another by a grid.

16. The method as claimed in claim 15, wherein the grid is cooled.
